(19) United States
(12) Patent Application Publication
(10) Pub. No.: US 2021/0391100 A1
(43) Pub. Date: Dec. 16, 2021

(54) Self-Assembling Antenna Networks and Antenna Feed Circuits for Same

(71) Applicant: Rosemount Inc., Shakopee, MN (US)

(72) Inventors: Jeffrey C. Andle, Rockledge, FL (US); Thomas M. Cunneen, Beverly, MA (US)

(73) Assignee: Rosemount Inc., Shakopee, MN (US)

(21) Appl. No.: 17/345,971

(22) Filed: Jun. 11, 2021

Related U.S. Application Data
(60) Provisional application No. 63/039,232, filed on Jun. 15, 2020.

(51) Int. Cl. H01B 11/06; H01B 7/17; G01R 31/12; H01Q 21/00

(52) U.S. Cl. CPC H01B 11/06; H01Q 21/0006; G01R 31/1272; H01B 7/17

(57) ABSTRACT

The disclosed embodiments provide a plurality of antennas that can be interconnected with each other and with a central receiver in a self-assembling manner, such that antennas can be added, removed, and replaced with minimal configuration. Each antenna comprises an antenna feed circuit, an input connector, and an output connector. Each of the antennas may be configured to assign a first set of signal channels at its output connector to a second set of signal channels at its input connector (or vice versa) according to a predetermined or dynamically determined mapping. Each antenna may be further configured to assign a signal channel at its input connector to the signal it receives at its antenna feed circuitry. By sharing the same configuration for mapping signal channels between the antennas' input and output connectors and feed circuitry, the antennas can be added or removed in a sequence of antennas using simple cable connections and without having to rewire the connections at the central receiver.

### CROSS REFERENCE TO RELATED APPLICATION

The present application claims the benefit of priority under 35 U.S.C. § 119(e) to U.S. Provisional Application No. 63/039,232, entitled “Self-Assembling Antenna Networks and Antenna Feed Circuits for Same,” filed Jun. 15, 2020, which is hereby incorporated by reference in its entirety as if fully set forth herein.

### FIELD OF THE INVENTION

The present invention generally relates to antenna networks and antenna feed circuits and, more specifically, to novel systems and methods for interconnecting a sequence of antennas and antenna feed circuits for implementing a self-assembled antenna network.

### BACKGROUND OF THE INVENTION

Distributed sensor systems used for the industrial internet of things (“IIoT”) often employ a central receiver and processing system connected to multiple antennas by antenna cables. Each antenna may be associated with, and may be located in close proximity to, one or more assets being monitored by sensors in the IIoT system. FIG. 1 illustrates an example of such a distributed sensor system 100. In this example, the IIoT system includes a set of assets 150a, 150b, 150c distributed across a geographic area. The distributed sensor system may deploy passive and/or active sensors 140a, 140b, 140c configured to detect and/or receive information about parameters, properties, states, or characteristics associated with the assets. Each sensor may detect, for example, electromagnetic, mechanical, thermodynamic, or other information associated with an asset, or receive output data from the asset (collectively “sensor data”). Each asset may be any component, module, system, equipment, device, etc. that can be monitored by one or more sensors. In FIG. 1, each sensor 140a-c is configured to monitor a respective asset 150a-c.

The distributed sensor system 100 includes a network of antennas 130a, 130b, and 130c distributed throughout the geographic area and configured to communicate with the distributed set of sensors 140a, 140b, and 140c. As shown, each antenna 130a-c is positioned to receive wireless signals transmitted from one or more sensors 140a-c located in relatively close proximity to their respective assets being monitored. Cables 120a, 120b, and 120c are used to connect each antenna 130a, 130b, and 130c to a corresponding input connection 115a, 115b, and 115c at a central receiver and processing system 110. Each cable 120a-c provides a physical transmission medium for carrying signals from a corresponding antenna 130a-c to the central receiver and processing system 110. Each cable 120a-c may, for example, consist of a conventional coaxial cable.

When the antenna locations in such distributed sensor systems are fixed and known, it is possible for the central receiver and processing system to deduce information about the location of a sensor based on which antenna(s) can observe the sensor. It is also possible for the central receiver and processing system to analyze sensor data that it receives from an antenna as being related to the health of an asset associated with the antenna. Traditionally such a distributed sensor system requires an administrator (or “installer”) to manually configure the system by connecting the plurality of cables from the central receiver to each of the plurality of antennas with the attendant chance of mistakenly crossing their connections.

In prior-art systems, installers place antennas as needed to provide signal coverage over an area and run individual cables from each antenna back to a corresponding input connection at the central receiver as FIG. 1 shows. For systems having a large number of antennas, there is a significant chance of error in making these cable connections at the correct inputs of the receiver. For systems using self-identifying digital sensors, a mistake in connecting the cables at the receiver could result in an error locating a sensor in the coverage area, although the correct location of the sensor eventually may be identifiable using its sensor data and/or digital signal processing. For analog sensors, however, especially those using multiple, indistinguishable sensors, an error in the antenna connections at the receiver could result in an incorrect assignment of sensor data in the IIoT system, e.g., erroneously attributing sensor data received from a first sensor as having been transmitted by a second sensor in the network.

In a specific example, a distributed sensor system uses wireless sensors to monitor the health of a high voltage switchgear. The switchgear consists of multiple compartments separated by metal barriers with each compartment containing a plurality of sensors and at least one antenna. During installation, each cable is first connected between one of the antennas and the receiver, then the signal integrities of the sensors are tested. This often requires adjustment of antenna locations. When a mistake is made in assigning antennas to different input connections at the central receiver, the installer is misinformed as to which antenna requires adjustment of its location. This simple mistake can dramatically extend the installation time, which necessarily is performed during a forced power outage.

Even when the system appears to function as planned, if the sensors are analog and cannot be positively identified—that is, when only antenna location is used to identify and distinguish otherwise identical sensors based on their locations near different antennas—critical operational and safety data transmitted by the sensors may be attributed to the wrong measurement location. Often the central receiver collects sensor data from multiple, adjacent switchgear, and the response to a detected abnormal condition is to take the affected switchgear out of service for inspection and repair. In the case of a cable wiring error at the receiver, the wrong equipment would be serviced. At a minimum, this would result in wasted time and expense. At the worst, the asset with anomalous conditions could fail despite a warning from the sensor because the wrong switchgear unit was inspected.

In other distributed sensor systems using nonstationary equipment, it is common to deduce the location of equipment based on which antenna or antennas in a network can measure the sensor located at or close to the equipment. Again, a mistake in cabling of the antenna network can lead to faulty location data.

Returning to the example of a switchgear system, often a plurality of antennas, and therefore a plurality of cables, must be routed from the central receiver to a single switchgear compartment. In many cases, only a single signal channel may be transmitted in each of these cables, and it is not always possible to route a sufficient number of cables. As used herein, a “signal channel” generally refers to a physical or logical channel used to transmit a signal. For example, a signal channel may correspond to one or more physical transmission mediums, such as metal wires and/or optical fibers, used to transmit a balanced or unbalanced signal. For example, a signal channel may correspond to a shielded twisted pair (“STP”) used to transmit a signal carrying sensor data from an antenna to the receiver. A signal channel alternatively may be implemented as a logical channel, such as corresponding to one or more predefined time slots or frequencies of a time-division or frequency-division multiplexed transmission. Accordingly, it is possible that a cable routed to an antenna in a switchgear compartment may only support a limited number of signal channels, although a plurality of additional signal channels would be needed to monitor sensor data from all of the sensors in that compartment.

In view of these limitations, prior-art solutions used cable splitters and couplers. These solutions divided a cable's signal power among various antennas, allowing multiple signal channels carried in a single cable to be split one or more times and coupled to the inputs of a plurality of antennas, for example, located in different switchgear compartments. Using such splitters and couplers, an unused signal channel of a cable from the central receiver routed to an antenna in a first switchgear compartment could instead be used to transmit sensor data received by an antenna in a second switchgear compartment. These solutions, however, had limitations in that the relative locations of individual sensors positioned near antennas along a cable were still unknown. These solutions were also disadvantageous because the signal splitting introduced losses that reduced signal quality of the signal channels used to transmit the sensor data to the central receiver.

There remains a current need for systems and methods that can simplify the installation and configuration of antenna-network topologies for IIoT systems comprising distributed wireless sensors for monitoring assets, such as switchgear used in electrical power generation and distribution systems.

### SUMMARY OF THE INVENTION

Unlike prior implementations, the disclosed embodiments comprise a plurality of antennas that can be interconnected with each other and with a central receiver in a self-assembling manner, such that antennas can be added, removed, and replaced with minimal configuration. For example, an installer in the disclosed embodiments may connect one or more input connections at the central receiver to a sequence of serially-connected antennas, with the central receiver and each adjacent antenna being connected using interchangeable cable bundles. In this configuration, antennas can be added or removed at any location in the sequence using simple cable connections and without having to rewire the input connections at the central receiver. In some embodiments, the antennas may be interchangeable without loss of functionality in a distributed sensor system.

In accordance with the disclosed embodiments, each antenna has an antenna feed circuit, an input connector, and an output connector. An installer may connect a first antenna's input connector to an input port at the central receiver using a first cable bundle. The antenna's output connector may be connected to the input connector of a second antenna using a second cable bundle. Similarly, the output connector of the second antenna may be connected to an input connector of a third antenna by a third cable bundle, and so on. Advantageously, each of the antennas may be configured to assign a set of output signal channels at its output connector to a set of input signal channels at its input connector (or vice versa) according to a predetermined mapping or pattern. The predetermined mapping or pattern may be statically configured or dynamically determined in the antenna. Each antenna may be further configured to route (direct) signals received from the antenna's feed circuitry to a predetermined signal channel at the input connector. By sharing the same configuration for mapping signal channels between the antennas' input and output connectors and antenna feed circuitry, each antenna can be interchangeably positioned in a serially-connected sequence (“chain”) of antennas. The sequence of antennas is self-assembling in the sense that antennas can be easily added, removed, or replaced in the sequence, as each antenna may be configured with the same predetermined mapping between its respective input signal channels, output signal channels, and antenna feed circuitry.

In some disclosed embodiments, a first signal channel at an antenna's input connector may be coupled to the antenna feed circuitry, thereby carrying the antenna's received signal. The antenna may include hardware and/or software for mapping and making connections between the other signal channels at the antenna's input connector relative to one or more signal channels at the antenna's output connector. For example, a second signal channel at the antenna's input connector may be connected to a first signal channel at the antenna's output connector; a third signal channel at the input connector may be connected to a second signal channel at the output connector; a fourth signal channel at the input connector may be connected to a third signal channel at the output connector, and so on. In this manner, the antenna can use its predetermined mapping to route signals and interconnect signal channels between cable bundles connected to the antenna's input and output connectors. In some embodiments, the predetermined mapping may be based on each antenna's indexed location in a chain of antennas, and the likelihood of crossing connections in such embodiments therefore can be significantly reduced.

Further to the disclosed embodiments, an installer may connect a first cable bundle to an input connector at the central receiver, direct or run this first cable bundle to the vicinity of a first asset to be measured at a first location, and connect a first antenna's input connector to the first cable bundle at or close to the first location. One or more sensors at the first location may communicate sensor data about or relating to the condition of the first asset to the first antenna. In addition, the installer may connect a second cable bundle to both an output connector of the first antenna and an input connector of a second antenna, where the second antenna is positioned in the vicinity of a second asset to be measured by one or more sensors at a second location. Additional antennas may be similarly added to form an ordered chain of antennas for receiving sensor data and information relating to a plurality of assets in a distributed sensor system, such as an IIoT system.

According to certain embodiments, the central receiver may be configured to receive the signal channels in the first cable bundle at a communication interface (“port”) having various input connectors. In such embodiments, a first antenna's feed circuitry may route the first antenna's received signals to a first signal channel of the first cable bundle, which the receiver would receive at an input connector corresponding to the first signal channel. The second antenna's feed circuitry may route its received signals to a first signal channel in the second cable bundle, but these signals would then be further routed to a second signal channel in the first cable bundle, which the receiver would receive at an input corresponding to the second signal channel. By logical extension, antenna feed circuitry of the Nth antenna in the chain would route its received signals to a first signal channel of the Nth cable bundle, which would then be further routed to a second signal channel of the (N−1)th cable bundle, a third signal channel of the (N−2)th cable bundle, and so on, including an Nth signal channel of the first cable bundle, which the receiver would receive at an input corresponding to the Nth signal channel.

In some applications and embodiments, it might be desirable to reserve at least one signal channel in the cable bundles for an alternate function. In such embodiments, for example, one or more signal channels in each cable bundle may be dedicated to carrying signals associated with at least one predefined function, independent of the self-assembly of the network of antennas. A signal channel that has been dedicated to a predefined function may, for example, carry control and/or data signals in connection with its associated function. Such signal channels preferably have a one-to-one mapping from each antenna's input connector to its output connector. For example, in some embodiments, at least the Nth signal channel of each cable bundle may be connected to the Nth signal channel in each adjacent cable bundle in the antenna chain and reserved for a predefined function in the antenna network or used to communicate other control and/or status information.

### BRIEF DESCRIPTION OF THE DRAWINGS

The particular features and advantages of the invention will become apparent from the following description taken in connection with the accompanying drawings in which like reference numbers indicate identical or functionally similar elements. The following figures depict details of disclosed embodiments. The invention is not limited to the precise arrangement shown in these figures, as the accompanying drawings are provided merely as examples:

FIG. 1, discussed above, is a schematic block diagram of a conventional distributed sensor system comprising a receiver and a network of antennas used to receive sensor data and information from a plurality of sensors that monitor assets in an IIoT system.

FIG. 2 is a schematic block diagram of an exemplary receiver with at least one communication port connected to a sequence of antennas and a special function device that may be used in accordance with certain disclosed embodiments of the invention.

FIG. 3 is a schematic diagram showing an example of an antenna's internal mapping of signal channels between input and output connectors and its antenna feed circuit that may be used in accordance with certain exemplary embodiments of the invention.

FIG. 4 is a schematic diagram showing an example of an antenna's internal mapping of signal channels that may be used for a two-antenna system having two functions per antenna in accordance with certain exemplary embodiments of the invention.

### DETAILED DESCRIPTION OF THE DISCLOSED EMBODIMENTS

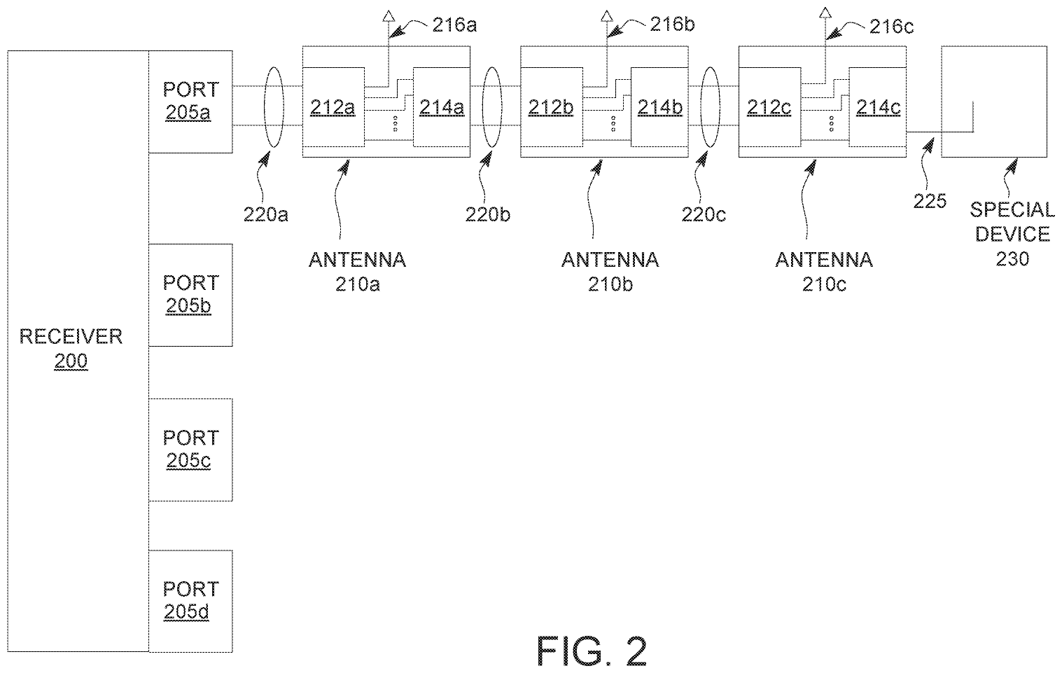

FIG. 2 illustrates an exemplary antenna network that may be used in accordance with embodiments of the invention. In FIG. 2, a receiver 200 is configured to receive signals, e.g., corresponding to sensor data, from a set of antennas 210a, 210b, and 210c. The receiver 200 also may include logic, circuitry, and processing capabilities (not shown) for processing signals it receives from the antennas 210a-c. In some embodiments, the receiver 200 may be coupled to a separate processing system (not shown) configured to process, or further process, the signals that the receiver receives from the antennas.

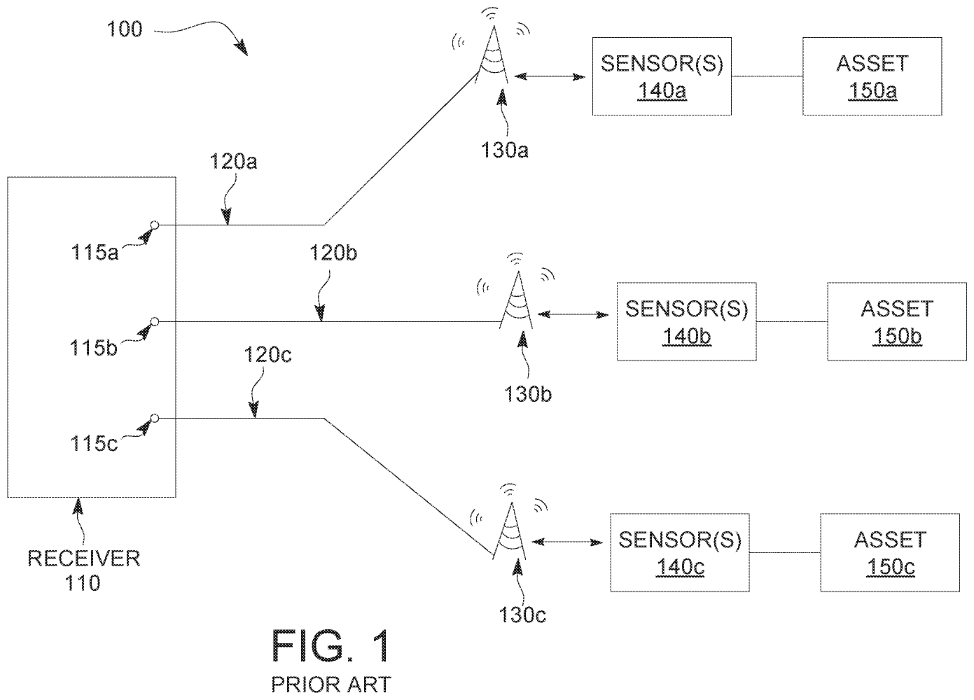

Each antenna 210a-c may be physically located in the vicinity of one or more assets that are measured by one or more sensors as described above with respect to FIG. 1. In some exemplary embodiments, each antenna 210a-c may be located in, or in close proximity to, switchgear compartments (not shown) for receiving sensor data associated with one or more assets in each compartment. The antennas 210a-c may receive wireless signals from one or more sensors using any wireless frequencies and protocols. In some embodiments, the antennas 210a-c may be configured to receive at least some sensor data over wired connections, e.g., if the sensor has been directly incorporated into or otherwise integrated with the antenna. The antennas 210a-c may receive wireless signals conveying sensor data relating to certain parameters, properties, states, or characteristics of assets being monitored in an IIoT system. The sensors may include any passive or active sensors configured to detect electromagnetic, mechanical, thermodynamic, or other information associated with an asset, or receive output data from the asset. Exemplary sensors may monitor, for example, the temperature, humidity, voltage, current, or any other information associated with assets in the IIoT system.

In FIG. 2, the receiver 200 is configured to receive signals from the antennas 210a-c and also may receive signals from at least one special device 230. The device 230 may provide control and/or data signals corresponding to functionality that is relevant to a particular implementation. For example, the special device 230 in FIG. 2 may provide signals corresponding to one or more radio-frequency identifiers (“RFID”) associated with assets being monitored in the IIoT system. In some embodiments, the device 230 may include processing capabilities for generating its control and/or data signals. The exemplary special device 230 is shown as a device that is separate from the antennas 210a-c, although alternatively the special device 230 and its functionality could be incorporated into one of the antennas or sensors.

Each antenna 210a-c comprises a respective input connector 212a-c, output connector 214a-c, and antenna feed circuitry 216a-c. Each input and output connector is configured to send and/or receive signals over signal channels of a cable 225 or cable bundle 220a-c. As used herein, a “cable” may consist of any type of physical medium for transmitting one or more signals, such as but not limited to a coaxial cable, shielded or insulated wires, shielded twisted pairs, optical fibers, and so forth; a “cable bundle” more generally refers to one or more cables, which may comprise the same or different types of physical transmission media, supporting a plurality of signal channels. In some embodiments, each signal channel in a cable bundle may correspond to a different physical transmission medium, such as a different shielded twisted pair of wires. In other embodiments, the signal channels in a cable bundle may correspond to any combination of physical and/or logical channels for carrying analog or digital signals. The input and output connectors 212a-c and 214a-c include the interface hardware and logic and associated software for sending and receiving signals over signal channels of a cable or cable bundle. To that end, each of the input connectors 212a-c and output connectors 214a-c includes a corresponding set of inputs (e.g., headers, connectors, or other input terminals) for connecting to one or more physical transmission media in a cable or cable bundle.

In the exemplary embodiment of FIG. 2, each antenna feed circuitry 216a-c may comprise or connect to a single physical antenna or a plurality of physical antennas, such as an antenna array, for communicating with sensors in an IIoT system. In some embodiments, the antenna feed circuitry 216a-c may be configured to combine multiple received signals based on conventional diversity techniques. The antenna feed circuitry 216a-c further may comprise front-end circuitry for processing signals transmitted and/or received by the antenna. The antenna feed circuitry 216a-c may include, or otherwise may be coupled to, any type of physical antenna(s), modulators, amplifiers, filters, mixers, oscillators, or other front-end and transceiver circuitry known in the art for sending and/or receiving wireless signals according to a wireless standard or protocol. In some embodiments, the antenna feed circuitry 216a-c may be configured to convert received radio frequency (“RF”) signals into digital signals for transmission over a signal channel. In operation, each antenna's feed circuitry may provide received antenna signals (analog or digital) to be transmitted over a signal channel of a cable bundle connected to the input connector.

Each antenna 210a-c also may comprise one or more physical processors (not shown), such as a microprocessor, microcontroller, digital signal processor, field programmable gate array, application specific integrated circuit, or the like, and may further include at least one non-transitory memory device for storing associated software or firmware, configured to control at least some operations of the input connectors 212a-c, output connectors 214a-c, and/or antenna feed circuitry 216a-c in accordance with the disclosed embodiments described herein.

As FIG. 2 shows, the receiver 200 includes a first connector port 205a and additional connector ports 205b, 205c, and 205d. Each of the ports 205a-d provides a network interface for connecting to the one or more cables of a cable bundle. Each port 205a-d also may include any necessary logic, circuitry, and/or other hardware, and associated software, for enabling the receiver to send and receive signals over a cable bundle connected to a remote antenna.

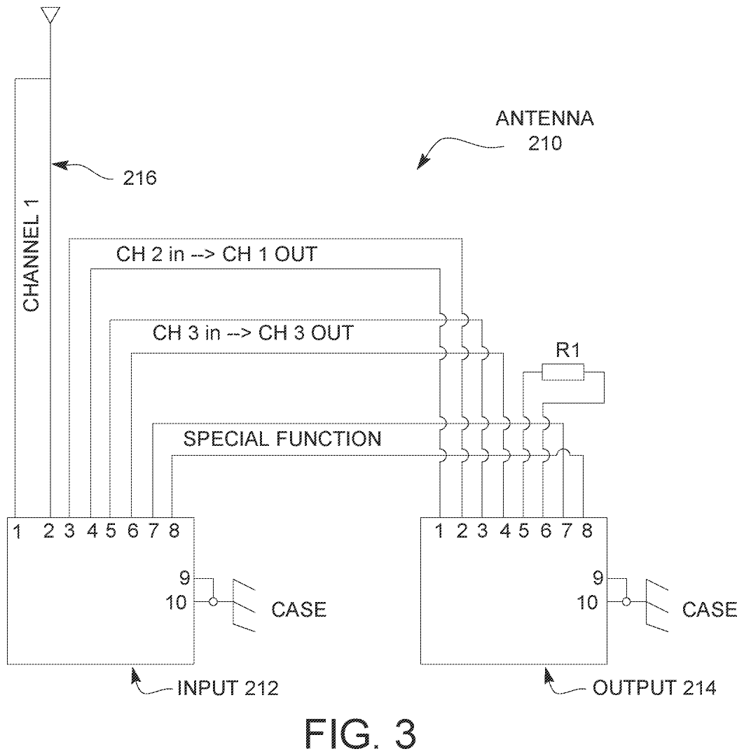

In this exemplary embodiment, the first connector port 205a is connected by a cable bundle 220a to an input connector 212a of an antenna 210a, which may have the same internal connections described below in the exemplary embodiment of FIG. 3. A second cable bundle 220b of similar or identical construction and function connects the output connector 214a of antenna 210a with the input connector 212b of antenna 210b. A third cable bundle 220c connects the output connector 212b of antenna 210b to the input connector 212c of antenna 210c. Special device 230 is connected to the output connector 214c of antenna 210c by a cable 225 in this example. While only one exemplary sequence of antennas is shown connected to the receiver 200 at its first port 205a, each of the other ports 205b, 205c, and 205d of the receiver similarly may be configured to receive signals transmitted on signal channels of cable bundles connected to other chains of sequentially-connected antennas.

In some disclosed embodiments, each antenna 210a-c is preferably interchangeable in the sequence of antennas and each cable bundle 220a-c is preferably an interchangeable bundle of one or more cables providing a plurality of signal channels. Because the antennas 210a-c and cable bundles 220a-c may be interchangeable, an installer can add, remove, and replace antennas in the system with less configuration than is conventionally required.

FIG. 3 is a schematic block diagram illustrating an exemplary antenna 210 where the input connector 212 and output connector 214 are configured to connect to cable bundles having four different signal channels. In this example, the signal channels 1, 2, and 3 are used to carry received antenna signals in each cable bundle, and the signal channel 4 in each cable bundle is reserved for carrying a signal corresponding to a special function, such as from the special device 230 in FIG. 2. As discussed below, the signal channels of a cable bundle connected to the input connector 212 are referred to as the “input signal channels”; the signal channels of a cable bundle connected to the output connector 214 are referred to as the “output signal channels.” According to the disclosed embodiments, the output signal channels may be assigned to the input signal channels according to a predetermined mapping. The predetermined mapping of output signal channels to input signal channels may be preconfigured within the antenna 210 or, alternatively, may be dynamically determined by a physical processor (not shown) in the antenna 210.

In the exemplary embodiment of FIG. 3, each input and output signal channel corresponds to a respective pair of wires, such as a shielded twisted pair, in a cable bundle. For example, each cable bundle connected to the input and output connectors 212 and 214 in FIG. 3 may contain at least four shielded twisted pairs, each corresponding to a different signal channel. Therefore, each cable bundle in this example contains at least eight wires, and the input and output connectors 212 and 214 include at least input terminals 1-8 for connecting to the eight wires in each cable bundle. The input and output connectors in this example also include input terminals 9 and 10 connected to an electrical ground potential on a metal case of the antenna 210.

In FIG. 3, the input signal channel 1 connects to the antenna feed circuit 216 and is used to carry the antenna's received signal, e.g., received from a sensor monitoring an asset in an IIoT system. The input signal channels 2 and 3 are connected to the output signal channels 1 and 2, respectively. The special function signal channel is preferably not shifted and, as FIG. 3 shows, the special function signal channel is present on both the input and output signal channel 4 regardless of whether input signal channels 1, 2, and 3 are used, and even if no antennas are placed between the special device 230 and the receiver 200. The unused output signal channel 3 at the output connector 214 is preferably terminated by a load resistor R1 to reduce cable crosstalk and noise induction.

In this exemplary embodiment, each of the input and output signal channels 1, 2, and 3 are respectively assigned to pairs of wires on the input and output connectors. For example, wires 1 and 2 on the input and output connectors may correspond to signal channel 1, wires 3 and 4 may correspond to signal channel 2, wires 5 and 6 may correspond to signal channel 3, and wires 7 and 8 may be assigned to the special function signal channel in this example. As noted above, each signal channel 1-3 and the special function signal channel at the input and output connectors may be implemented using a different shielded twisted pair in a cable bundle. However, within the antenna 210 the interconnection of the input signal channels and output signal channels may utilize other types of physical transmission media. Those skilled in the art will appreciate that the signal channels may be assigned to any predetermined wire(s) on the input and output connectors in other embodiments. In addition, while FIG. 3 shows an example where each of the signal channels at the input and output connectors is assigned an index from 1 to 3, those skilled in the art will appreciate the invention is more generally applicable to any number N of signal channels that may be supported in a particular implementation.

FIG. 3 illustrates one possible representation of internal connections between an input connector 212, antenna feed circuit 216, and output connector 214 that may be used to assign signal channels in accordance with the disclosed embodiments. In particular, FIG. 3 shows an exemplary embodiment in which wires 1 and 2 at the input connector are a differential signal feed corresponding to input signal channel 1 connected to the feed circuit of the antenna, while wires 3 and 4 at the input connector correspond to input signal channel 2 and are connected to wires 1 and 2 at the output connector corresponding to output signal channel 1. In this exemplary embodiment, wires 5 and 6 corresponding to input signal channel 3 at the input connector are connected to wires 3 and 4 corresponding to output signal channel 2 at the output connector, and wires 5 and 6 corresponding to output signal channel 3 at the output connector are terminated, e.g., connected to a load resistor R1, or alternatively may be left disconnected (open circuit).

The physical connections for mapping the wires 1-6 between the input and output connectors 212 and 214 in FIG. 3 may be hardwired in the antenna 210 or, alternatively, these connections between the input and output connectors may be programmatically determined, for example, by a physical processor (not shown) in the antenna 210 or located remotely, such as at the receiver 200 or another antenna or another network location. For example, in some embodiments, a controller in the antenna 210 may be configured by logic, firmware, and/or software instructions stored in a memory to control one or more relays, switches, or fuses to selectively connect various wires at the input connector 212 to wires at the output connector 214 and to the antenna feed circuit 216 in accordance with a predetermined mapping.

Advantageously, in the example of FIG. 3, the predetermined mapping between the connections of the wires 1-6 at the input and output connectors and the antenna feed circuit allow up to three identically-wired antennas 210a-c to self-assemble on signal channels 1-3, sequentially, based on the order in which they are connected, for example as shown in FIG. 2. Wires 7 and 8 forming signal channel 4 at both the input and output connectors are passed directly through each of the antennas 210a-c, allowing the special function to exist on the same wires at each antenna 210a-c regardless of the number of intervening antennas.

In some embodiments, a plurality of signal channels at the input and/or output connectors may be used to provide signal diversity, for example, where an antenna receives multiple signals from the same or related sensors. In addition, while the assignment of input and output signal-channel numbers to the wire terminals at the input and output connectors is preferably predefined, in some embodiments they also could be dynamically assigned, for example, by a controller (not shown) configured to manage the channel-to-wire assignments.

Referring again to FIG. 2, each antenna 210a-c may be configured to correlate input and output signal channels according to the same predetermined mapping shown in the example of FIG. 3. In such an embodiment, each antenna 210a-c may be interchangeable in the chain of antennas coupled to the port 205a of receiver 200. As such, connecting the second interchangeable antenna 210b, in which the input connector of the second antenna is connected to the output connector of the first interchangeable antenna 210a, places the received antenna signal from the antenna feed circuit of the second antenna 210b onto signal channel 2 at the receiver's first port 205a. Connecting the third interchangeable antenna 210c, in which the input connector of the third antenna is connected to the output connector of the second interchangeable antenna 210b, places the received antenna signal from the antenna feed circuit of the third antenna 210c onto signal channel 2 at receiver port 205a.

In the exemplary embodiment of FIG. 2, when each antenna 210a-c employs the predetermined mapping of FIG. 3, the sequentially-connected antennas 210a-c connected to the first port 205a of the receiver 200 automatically connect to the port's signal channels in the order of their attachment. That is, the received antenna signal from the first antenna 210a is received at “port 1: channel 1,” the antenna signal from the second antenna 210b is received at “port 1: channel 2,” the antenna signal from the third antenna 210c is received at “port 1: channel 3,” and the transmitted signal from the special function device 230 is received at “port 1: channel 4.”

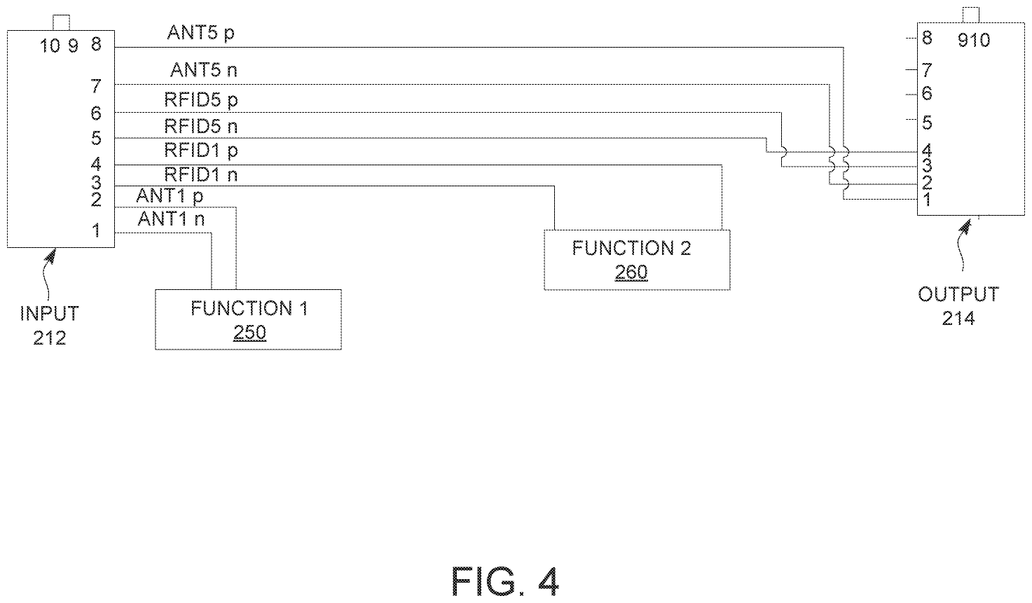

FIG. 4 is a schematic block diagram of exemplary antenna that may be used in accordance with certain disclosed embodiments. In FIG. 4, a cable bundle connected to the input connector 212 of the antenna has four pairs of wires forming four signal channels. The exemplary antenna in FIG. 4 has two associated functions, e.g., a first antenna feed 250 (“Function 1”) for receiving partial discharge signals to perform a partial-discharge function, and a second antenna feed 260 (“Function 2”) for RFID sensor transceiver functions. In this example, a first pair of wires 1 and 2 on the input connector 212 is designated “ANT1” for function 1, and a second pair of wires 3 and 4 is designated “RFID1” for function 2. A third pair of wires 5 and 6 on the input connector 212 may be connected to a pair of wires 3 and 4 on the output connector 214 corresponding to a signal channel carrying RFID information received from another antenna. A fourth pair of wires 7 and 8 on the input connector 212 may be connected to a pair of wires 1 and 2 on the output connector 214 corresponding to a signal channel carrying partial discharge signals received from another antenna.

In some embodiments, each antenna 210 may utilize more than one signal wire or wire pair per signal channel, and the mapping of signal channels between an antenna's input connector and its output connector may be performed by shifting the physical wire connections between the output and input connectors by the number of wires per channel. Such a process for shifting between different sets of wires assigned to channels on input and output connectors may be performed as described, for example, in U.S. patent application Ser. No. 16/580,251, entitled “Antenna connectivity with shielded twisted pair cable,” to J. Andle, filed on Sep. 24, 2019, which is hereby incorporated by reference in its entirety.

In an exemplary case, a CAT-8 shielded twisted pair could have two signal channels defined as a first twisted pair for partial discharge monitoring and a second twisted pair for passive wireless sensor measurements. Since a typical CAT-8 cable comprises four shielded twisted pairs, there are sufficient wire pairs for the two signal channels in this example.

Numerous modifications, changes, and other embodiments of the invention herein disclosed will suggest themselves to those skilled in the art. It is to be understood that the present disclosure relates to certain disclosed embodiments of the invention which are for purposes of illustration and explanation only and are not to be construed as a limitation of the full scope of the invention. All such modifications which do not depart from the spirit of the invention are intended to be included within the scope of the appended claims.

For example, the figures and descriptions in the disclosed embodiments depict a central receiver and antennas that function as receivers; however, the invention described herein applies equally to transmitters, monostatic transceivers, and bistatic transceivers. More generally, the antennas 210a-c may be used to receive and/or transmit signals in an IIoT system. Further, the invention is not limited to any particular antennas, sensors, assets, equipment, or IIoT systems that may have been described for purposes of explanation as examples in the disclosed embodiments.

In addition, the figures and descriptions in some disclosed embodiments depict pairs of wires for each signal channel, which may be twisted pairs or shielded twisted pairs, but the invention is equally applicable using cables and cable bundles comprising other types of physical transmission media for providing the signal channels, including for example single-wire signals referenced to a common ground wire, e.g., unbalanced signals that may be carried on one or more of the signal channels in the cable bundles of the disclosed embodiments. Furthermore, hybrid systems with some differential signals and some single-ended signals may be used in multi-function embodiments. In some embodiments, one or more signal channels in a cable bundle may correspond to shielded twisted pairs that provide balanced transmission media, and the antenna feed circuits may be configured to provide signals from unbalanced antenna structures to the STP balanced transmission media in the cable bundle.

Solely for purposes of discussion and explanation, the input and output connectors 212a-c and 214a-c described with reference to FIGS. 2-4 have been labeled as “input” or “output” connectors to differentiate their relative locations in each antenna 210a-c. These descriptive labels, however, should not be interpreted as limiting any functionality or operation of any of the disclosed connectors 212a-c or 214a-c. For example, in the exemplary embodiments described herein, signals are passed from signal channels at an output connector to an input connector within an antenna, i.e., in a direction heading toward the receiver 200. In alternative embodiments, there may be one or more signals transmitted in the opposite direction, e.g., from an input connector to an output connector within an antenna. Similarly, the designations of first, second, third, etc. in connection with antennas in the disclosed chains of antennas are logical designations of the antennas' indexes in the chain and not necessarily geometrical designations based on the antennas' physical locations. Similarly, the designations of first, second, third, etc. in connection with signal channels in the disclosed embodiments are logical designations of signal channel indexes and not necessarily based on physical locations.

The disclosed embodiments also depict exemplary antenna signals; however, other signals and systems, for example, considered in the above-identified U.S. patent application, “Antenna connectivity with shielded twisted pair cable,” also may be multiplexed into self-assembled networks using the present invention. For example, while radio frequency (“RF”) signals may be transmitted over the signal channels in the exemplary disclosed embodiments, one or more of the signal channels alternatively may be configured to transmit other types of signals, such as but not limited to optical or microwave signals, where such embodiments also may use converters between different signal channel transmission media.

Those skilled in the art will also appreciate that other modifications and alternatives may be implemented in accordance with the exemplary embodiments described herein. For example, the physical wire connections at the input and output connectors and receiver port may be implemented in various ways, including both direct and/or indirect connections (such as using one or more signal couplers, filters, digital-to-analog converters, analog-to-digital converters, buffers, and so forth. Also, in the exemplary embodiments the antennas may be configured to receive signals from sensors and special devices over wired connections or wireless links using any network or communication standards or protocols. In some embodiments, one or more of the sensors in the IIoT system may be identified with a readable serial number and, further, one or more antennas in the antenna network also may be identified with a readable serial number making them one of the sensors in the IIoT system. In an exemplary embodiment, for example, the central receiver may self-assemble the antenna network based on the internal sensor aspect of each antenna and, in a further exemplary embodiment, the receiver may be configured to validate the installation of the antennas in the network.

Those skilled in the art will further appreciate that while the exemplary embodiments described herein relate to antenna networks employed in a distributed sensor system, the advantages of the inventive self-assembling antenna network is more generally applicable in any system that may employ sequences of antennas as described herein. In some implementations, for example, one or more of the antennas may be part of, integrated with, or otherwise included in another system or device. While the self-assembling antennas in the exemplary disclosed embodiments have been described in the context of distributed sensor systems, such as IIoT systems, the antennas alternatively may be employed in any system or network having transmitters (sensors or otherwise) distributed in a geographic area that communicate with antennas that may be arranged as self-assembling antenna networks described herein.

We claim:

1. An antenna comprising:
an input connector having a first set of inputs corresponding to a first input signal channel and one or more additional input signal channels, wherein the first set of inputs at the input connector are configured to connect to physical transmission media in a first cable bundle;
an output connector having a second set of inputs corresponding to a plurality of output signal channels, wherein the second set of inputs at the output connector are configured to connect to physical transmission media in a second cable bundle; and
an antenna feed circuit configured to route a wireless signal received by the antenna to the first input signal channel at the input connector,
wherein the plurality of output signal channels at the output connector are connected to the one or more additional input signal channels at the input connector according to a predetermined mapping.

2. The antenna of claim 1, wherein each of the one or more additional input signal channels at the input connector and each of the plurality of output signal channels at the output connector has an associated index number, and the predetermined mapping provides for a connection of each input signal channel with an index of N at the input connector to an output signal channel with an index of (N−1) at the output connector, where N is greater than or equal to 2.

3. The antenna of claim 1, wherein the physical transmission media in the first cable bundle comprises a different shielded twisted pair for each input signal channel at the input connector, and wherein the physical transmission media in the second cable bundle comprises a different shielded twisted pair for each output signal channel at the output connector.

4. The antenna of claim 1, wherein the first cable bundle is connected to both the input connector of the antenna and to a communication interface at a central receiver.

5. The antenna of claim 1, wherein the second cable bundle is connected to both the output connector of the antenna and an input connector of an adjacent antenna.

6. The antenna of claim 5, wherein the adjacent antenna is an identical antenna configured according to the same predetermined mapping for making connections between input signal channels and output signal channels in the adjacent antenna.

7. The antenna of claim 5, wherein the antenna and the adjacent antenna are included in a sequence of antennas connected to a central receiver in a distributed sensor system.

8. The antenna of claim 1, wherein the first cable bundle and the second cable bundle are interchangeable.

9. The antenna of claim 1, wherein the predetermined mapping provides for a first output signal channel to be connected to a second input signal channel, a second output signal channel to be connected to a third input signal channel, a fourth output signal channel to be connected to a fourth input signal channel, and a third output signal channel to be terminated by a load.

10. The antenna of claim 1, wherein the antenna further comprises a second antenna feed circuit configured to receive a second wireless signal, and wherein the predetermined mapping provides for the second wireless signal to be routed to a second input signal channel, a first output signal channel to be connected to a third input signal channel, a second output signal channel to be connected to a fourth input signal channel, and a third output signal channel and a fourth output signal channel to be terminated.

11. The antenna of claim 1, wherein one of the plurality of output signal channels is reserved for carrying a signal corresponding to a predefined function.

12. The antenna of claim 11, wherein each of the one or more additional input signal channels at the input connector and each of the plurality of output signal channels at the output connector has an associated index number, and the output signal channel that is reserved for carrying the signal corresponding to the predefined function is connected to an input signal channel having the same index number.

13. The antenna of claim 11, wherein the signal corresponding to the predefined function was generated by a remote device.

14. The antenna of claim 1, wherein the wireless signal is received from a sensor in a distributed sensor system.

15. The antenna of claim 14, wherein the sensor is configured to provide sensor data corresponding to an asset in a high voltage switchgear.

16. The antenna of claim 1, wherein at least one of the first cable bundle or second cable bundle comprises more than one type of physical transmission media.

17. The antenna of claim 1, wherein at least two of the plurality of input signal channels are configured to provide signal diversity.

18. A system comprising a self-assembling sequence of antennas connected to a communication interface at a central receiver, wherein each antenna in the self-assembling sequence of antennas comprises:
an input connector having a first set of inputs corresponding to a first input signal channel and one or more additional input signal channels, wherein the first set of inputs at the input connector are configured to connect to physical transmission media in a first cable bundle, and further wherein the physical transmission media in the first cable bundle are configured to connect to an output connector of a first adjacent antenna or to the communication interface at the central receiver;
an output connector having a second set of inputs corresponding to a plurality of output signal channels, wherein the second set of inputs at the output connector are configured to connect to physical transmission media in a second cable bundle, and further wherein the physical transmission media in the second cable bundle are configured to connect to an input connector of a second adjacent antenna; and
an antenna feed circuit configured to route a wireless signal received by the antenna to the first input signal channel at the input connector,
wherein the plurality of output signal channels at the output connector are connected to the one or more additional input signal channels at the input connector according to a predetermined mapping.

19. The system of claim 18, wherein, for each antenna in the self-assembling sequence of antennas, each of the one or more additional input signal channels at the input connector and each of the plurality of output signal channels at the output connector of the antenna has an associated index number, and the predetermined mapping provides for a connection of each input signal channel with an index of N at the input connector to an output signal channel with an index of (N−1) at the output connector, where N is greater than or equal to 2.

20. The system of claim 18, wherein the self-assembling sequence of antennas further comprises at least one device for providing signals corresponding to a predefined function.
